(19) United States
(12) Patent Application Publication
(10) Pub. No.: US 2015/0364754 A1
(43) Pub. Date: Dec. 17, 2015

(54) Silicene nanocomposite anode for lithium ion battery

(71) Applicants: Elwood James Egerton, Hot Springs, SD (US); Joan Francis Howard, Hot Springs, SD (US); James Darrell Rowatt, Fort Collins, CO (US); Richard Michail Altobellis, Mead, CO (US)

(72) Inventors: Elwood James Egerton, Hot Springs, SD (US); Joan Francis Howard, Hot Springs, SD (US); James Darrell Rowatt, Fort Collins, CO (US); Richard Michail Altobellis, Mead, CO (US)

(73) Assignee: Paideia LLC, Hot Springs, SD (US)

(21) Appl. No.: 14/545,573

(22) Filed: May 21, 2015

Related U.S. Application Data
(60) Provisional application No. 61/997,187, filed on May 22, 2014.

(51) Int. Cl. H01M 4/36; H01M 4/133; H01M 4/38; C30B 29/06; H01M 4/1395; H01M 4/04; C30B 25/02; H01M 4/134; H01M 4/587

(52) U.S. Cl. CPC H01M 4/364; H01M 4/134; H01M 4/133; H01M 4/386; H01M 4/587; H01M 4/1395; H01M 4/0404; H01M 4/0428; C30B 25/02; C30B 29/06; H01M 2004/027

(57) ABSTRACT

A higher capacity silicene thin film structure with alternating layers of silicon nanoparticles which will result in an anode for lithium ion batteries. This nanocomposite structure will increase the specific capacity to 3500 mAh/g-1 versus 350 mAh/g-1 for state of the art lithium batteries. Charge/discharge cycles of 5000 with a maximum of 15% loss are also achievable. This is due to the silicene nanocomposites' capability to accommodate the mechanical expansion of the lithiated silicon species. Reliability defects such as copper cracking and delamination will be minimized using a barrier/adhesion metal layer. This will also reduce copper dendrite formation. Particle cracking and lithium plating will also be reduced by using the silicon based nanocomposite. The silicene nanocomposite can be fabricated using UHV-CVD methods minimizing transition to high rate production and recurring manufacturing product costs.

### FIELD OF THE INVENTION

This invention is to create an improved lithium ion battery by the use of silicene in the structure of the anode. This will result in a larger storage capacity than the current state of the art lithium ion graphitic anodes˜372 mAh g-1 to ˜4200 mAh g-1 as well as higher reliability my extending anode material lifetime and minimizing copper/silicon interface delamination.

### BACKGROUND OF THE INVENTION

Utility:

This is an introduction to the patent application for an improved Li Ion battery (LIB) by initially replacing the anode with a silicene based nanocomposite comprised of two embodiments. Batteries remain the Achilles heel for many applications and a major obstacle for efficient uses of alternative energy production. Better batteries are needed for portable electronics, cars, toys, and medical electronics. Better batteries are needed for Solar, wind and smart electrical grid applications. So what is a better battery? The DOE has stated that “ . . . no batteries can meet the criteria that are required for tomorrow's energy storage needs.” The proposed invention would be inserted into a state of the art LIB manufacturing process flow and the resulting battery would have higher specific capacity, greater safety, equivalent or lower unit product cost, greater product life and minimal capacity fade, less environmental toxicity, wider operational temperature range.

Current Issues of Li-Ion Batteries:

State of the art (SOA) Lithium Ion Batteries have several major limitations. LIBs, developed in the last twenty years have several deficiencies that are creating a demand not currently met by battery device technologies. These deficiencies include:

The requirement for higher energy density: SOA Li-Ion battery (LIB) are capable of a theoretical storage capacity of 372 mA h/g. This is due to the fact that current Li-Ion batteries use graphite for the cathode and every six carbon atoms can host only one Li ion by forming an intercalation compound of LiC6. Other materials have higher theoretical storage capacity but have other properties that has limited product implementation, but as the invention application will discuss, issues such as material pulverization and life time capacity fade can be overcome to enhance LIB storage capacity. Silicon anodes have had limited application because of the volume change (400%) associated with the insertion and extraction of each Li atom. Silicon/silicene can accommodate 4.4 Li atoms leading to Li22Si5 alloy. Stresses associated with this volume change causes pulverization and cracking of previous silicon anodes. This effect also leads to delamination of the silicon-copper interface of the ion collector resulting in loss of electrical contact and fading of capacity.

Thermal management remains one of the major obstacles to improved LIB operation. These effects have limited the performance of current LIBs. Available energy is lost when materials inside the battery have been transformed into inactive phases resulting in reduced capacity at discharge. LIBs have suffered from safety issues due to combustion in several applications. SOA LIBs experience thermal runaway conditions. Thermal runaway occurs when elevated temperatures trigger heat generating exothermic reactions. The heat is not dissipated. The images of an expensive Tesla car burning due to the thermal runaway problem in LIBs is a result. As the battery is charged and discharged a film is deposited on the anode (Solid electrolyte interface—SEI) this film is decomposed by heat in the cell. The decomposition causes a lithium compound to react and generate heat resulting in thermal runaway and fire.

LIBs have faster charge/discharge rate over required temperature range. However, LIBs don't work well at lower temperatures (−30 C) and the mechanism of failure is not well understood. But this effect limits applications such as electric cars, aircraft and DOD/NASA applications. Zhang′ has argued that poor performance of LIBs at low temperature is linked to poor charge transfer at the electrode/electrolyte interface. This could lead to significant plating on the negative electrode during charging. ¹ S. S. Zhang, K. Xu and T. R. Low, Journal Electrochemical Society, 7,147 (1985)

SOA LIBs have more durable cycling performance-electrochemical and materials stability to ensure long lifetimes-minimize capacity fade. LIBs single cell voltage ˜3.5 V is not useful for most applications. They are connected in series to achieve the operating voltage. Mismatch in voltages can result in Li plating on negative electrode or oxygen loss from the positive electrode which in turn can lead to thermal runaway.

Current LIBs can be produced at reasonable Cost <$200 per kWh. But lower cost ($150 per kWh) is required for greater market adoption. Various approaches are described that may fix some of the limitations of LIBs but are not necessarily cost effective. These include silicon nanowires, silicon nanorods, silicon nanotubes, silicon/carbon composites and various other techniques.² But these approaches have not been shown to be cost effective. Any approach that is not optimizing economies of scale is not going to survive in the market place except possible niche markets. It has to be able to be manufactured competitively to be successful. The invention described in this application can be manufactured by either chemical vapor deposition or sputter deposition. Process equipment can be adapted from the semiconductor industry to obtain similar economies of scale and minimize the nonrecurring engineering costs. ² Teki, Ranganath, Moni K. Datta, Rahul Krishnan, Thomas C. Parker, Toh-Ming Lu, Prashant N. Kumta, and Nikhil Koratkar. “Nanostructured silicon anodes for lithium ion rechargeable batteries.” Small 5, no. 20 (2009): 2236-2242.

State of the art Li-Ion batteries consist of several components: These include a metal foil current collector made of either aluminum or copper, anode and cathode particles, a binder made of a polymer, conducting carbon particles, a polymer separator and an electrolyte consisting of organic and salt additives. This is displayed in figure Number One.

Silicene is a new two dimensional material which has many advantages for replacing graphitic based anodes in current LIBs. Silicene has properties³ such as strong structural integrity which makes it very advantageous in the two embodiments of a silicon silicene nanocomposite anode described in this applications. Silicene tends to form by the addition of thermal energy on a suitable template which makes it useful from a processing aspect. From the aspect of a battery silicene has properties in the properly designed anode can be very useful to a battery. These include 1.) Silicene provides much higher specific capacity. (˜3500 mAh/g-1) 2.) Facile ion transport through the structure enhanced by diffusion channels and in-plane silicon vacancies in both the silicene sheets and silicon nanoparticles. 3.) Superior electrical conductivity and packing density. 4.) Excellent structural integrity due to the high flexibility of the silicene sheets and nanoporous silicon nanoparticles which can accommodate the large volume changes of lithiated silicon compounds. ³ Kara, Abdelkader, Hanna Enriquez, Ari P. Seitsonen, L C Lew Yan Voon, Sébastien Vizzini, Bernard Aufray, and Hamid Oughaddou. “A review on silicene—new candidate for electronics.” Surface science reports 67, no. 1 (2012): 1-18.

### SUMMARY OF THE INVENTION

In accordance with the illustrative embodiment, the invention consists of the use of silicene amorphous and crystalline films deposited via differing methods including Ultra high vacuum chemical vapor deposition. The films properties are such that the porosity of the film is maximized from 0.1 to 1 g/cm³. The pores in the silicon film enables the overall silicene nanostructure will accommodate the physical expansion of the lithiated silicon compounds. Films at the lower edge of this range have resulted in specific capacities of 3-4× the SOA LIBs.

Silicene a 2D crystalline and amorphous film is made up of silicon also. The composite nanostructure consist of films with the property of porosity as defined in [0009]. One embodiment consist of one atomic layer silicene films followed by a layer of silicon nanoparticles 2-20 angstroms apart attached to the silicon film beneath it with the application rapid thermal anneal of 300 degrees C. for one minute. This causes the nanoparticles to attach to open silicene bonding sites. This approach can be limited due to the low mass fraction of the active component in the battery anode. This in turn results in loss of volumetric energy densities.

This embodiment using silicene sheets which possess high density silicon vacancies which is transformed into a 3-D conducting silicene scaffold. This approach has the properties of excellent cross plane ion diffusivity and resistance to structural deformation. A composite is created in this embodiment by the addition of silicon nanoparticles resulting in a ductile composite. Vacancies are induced in the silicene sheets by wet and dry chemical methods. The resulting structure has several advantages over the state of the art graphitic anodes used in lithium ion batteries. 1.) Silicon/silicene provides much higher specific capacity. (˜3500 mAh/g-1) 2.) Facile ion transport through the structure enhanced by diffusion channels and in-plane silicon vacancies in both the silicene sheets and silicon nanoparticles. 3.) Superior electrical conductivity and packing density. 4.) Excellent structural integrity due to the high flexibility of the silicene sheets and nanoporous silicon nanoparticles which can accommodate the large volume changes of lithiated silicon compounds.⁴. ⁴ Le Lay, G., B. Aufray, C. Léandri, H. Oughaddou, J-P. Biberian, P. De Padova, M. E. Dávila, B. Ealet, and A. Kara. “Physics and chemistry of silicene nano-ribbons.” Applied Surface Science 256, no. 2 (2009): 524-529.

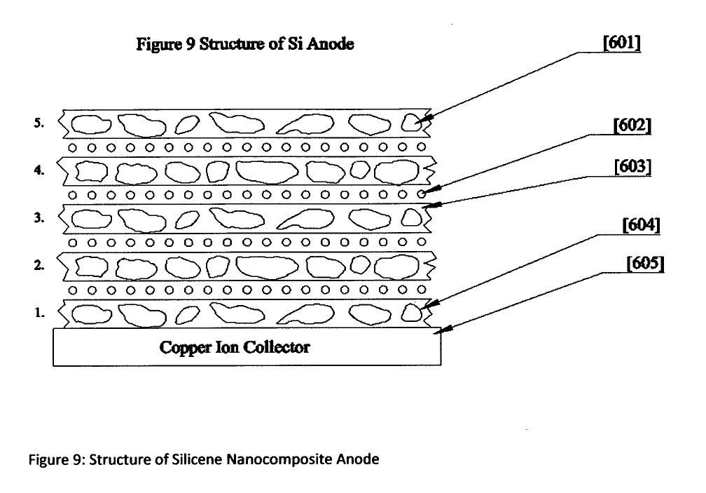

The second embodiment is shown in FIG. 9. SOA commercial Li-ion batteries have ˜50 micron thick cathode and about the same graphite based anode. The graphite has ˜350 mAh/g of capacity but its thickness is about the same because of its lower density. Considering the capacity of Si (in theory ˜3500 mAh/g), we would need one tenth of the graphite anode thickness. It is anticipated that the overall thickness of the layers would have a total thickness of ˜5-10 microns. The nanoparticles have a diameter of 50-300 nm. And in the case of the of the carbon nanotube nonaligned film which would have a thickness of 3-10 angstroms. The silicene layers are deposited on top of the porous silicon films using a crystalline metal interface layers such as Ag or diborane or an epitaxial crystalline silicon layer. The silicene layer are modified to create silicon vacancies with wet and dry etch methods. The silicon nanoparticles are spun on centrifugally and are annealed at 300-400 degrees centigrade for one minute using a rapid thermal anneal method. The resulting nanoporous silicon thin film—silicene sheets—silicon nanoparticle composite has excellent structural integrity.

The resulting nanocomposite has several advantages over the graphitic anodes used in LIB: 1.) Silicon/silicene provides much higher specific capacity. (˜3500 mAh/g-1) 2.) Facile ion transport through the structure enhanced by diffusion channels and in-plane silicon vacancies in both the silicene sheets and silicon nanoparticles. 3.) Superior electrical conductivity and packing density. 4.) Excellent structural integrity due to the high flexibility of the silicene sheets and nanoporous silicon nanoparticles which can accommodate the large volume changes of lithiated silicon compounds.⁵ ⁵ Le Lay, G., B. Aufray, C. Léandri, H. Oughaddou, J-P. Biberian, P. De Padova, M. E. Dávila, B. Ealet, and A. Kara. “Physics and chemistry of silicene nano-ribbons.” Applied Surface Science 256, no. 2 (2009): 524-529.

### DETAILED DRAWING DESCRIPTIONS

Drawing Number 1: Lithium-Ion Rechargeable Battery Operation

Drawing Number 2: Weight Output Density versus Weight Energy Density

Drawing Number 3: Amorphous and Crystalline Silicene

Drawing Number 4: Multilayer Silicene with Si Nanoparticles

Drawing Number 5: Silicene-Silicon Nanoparticle Cross Section

Drawing Number 6: UHV-CVD Growth of Silicene

Drawing Number 7: Silicene-Silicon Nanoparticle Process Flow

Drawing Number 8: DC/RF Sputter Deposition of Silicon/Silicene

Drawing Number 9: Structure of Silicene Nanocomposite Anode

### DETAILED DESCRIPTION

Components of the state of the art lithium ion battery include, a metal foil current collector made of either aluminum or copper [107,102], anode and cathode particles [101,109], conducting carbon particles [109] which is composed of graphitic material consisting of layers of graphene. A polymer separator [105] which separates the anode and cathode physically from each other. An electrolyte [106] consisting of organic and salt additives. In LIB, two materials with differing electron affinities are used as cathode and anodes. Electrons flow from one electrode to the other outside of the battery, the electrolyte closes the internal part of the battery by its ions.

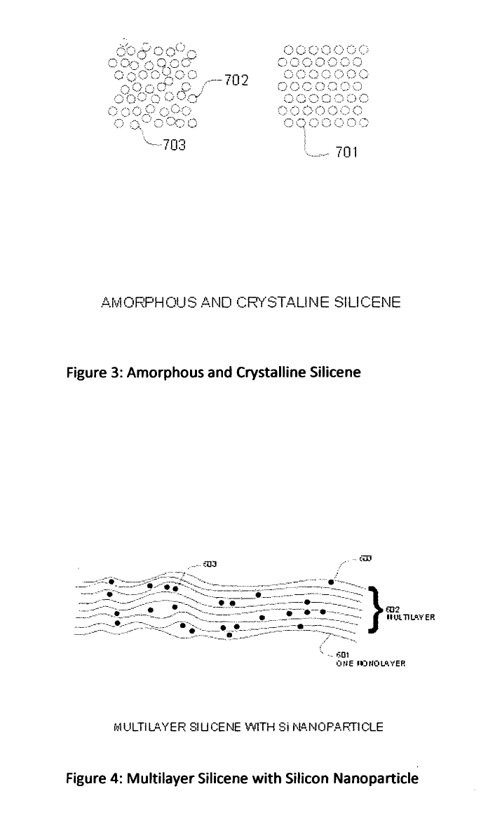

One of the current embodiments the cathode consists of a LiMO2 or LiFePO4 layer structure [102] which serves as the source of Li+. The electrolyte [106] provides a conductive medium to enable Li+ to move between the electrodes. During discharge [109] positive Li Ions move from the anode to the cathode [101] (which contains Li). During charging Li Ions move from the cathode [102] to the anode. [107] In the current state of the art Li-Ion batteries the anode [107] is composed of graphite sheets but this limits it specific capacity. This invention replaces the graphitic anode with silicene nanostructure as defined in FIGS. 4, 5, and 9.

The specific capacity is 372 mHh/g for carbon and 339 mAh/g for LiC6. The Graphite density 2.25 g/cc volumetric capacity 840 mAh/cc˜interlayer distance increase by 10%. The distance increase minimizes the probability of pulverization and the resulting lifetime performance degradation.

The invention relates to replacement of a anode in one embodiment with a multilayer nanoporous silicon with a silicene structural layer and a second embodiment with a multi-layer silicene sheets, upon which silicon nanoparticles are attached using Silicon-Silicon bonding and then another thin film is deposited on top of the nanoparticles and then the process is repeated up to ten times to achieve the silicon thin films-silicon nanoparticles nanocomposite. See figure number nine.

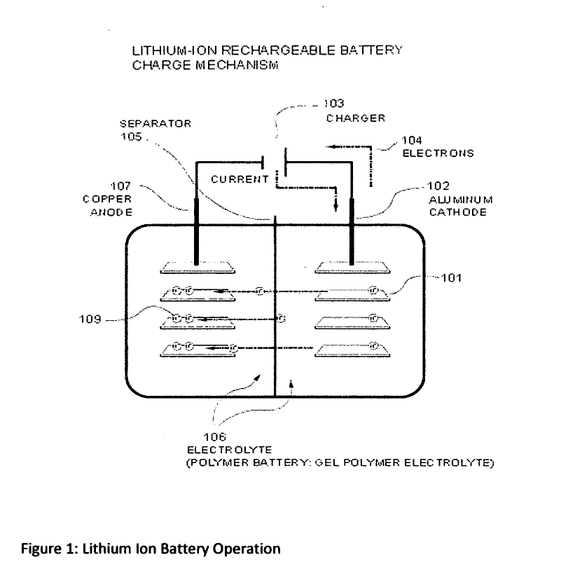

This invention and the proposed replacement anode material requires the following requirements. First the replacement silicon or silicene nanocomposite material should have high gravimetric and volumetric capacity as shown in FIG. 2. [201,202] It is well known that silicon can be used as active anode material in a LIB.⁶ Silicon has increased gravimetric and volumetric capacity over Li metal, Li Ge, Li Sn, Li Al and LiZn. (Li4.4Si 4200 mAh/g of silicon, 9786 mAh/cm³) ⁶ Winter, M. Vesenhard, B. Spahr, M. E. and Novuk, P., Adv. Materials, 1998, No. 10, 10

Silicon/silicene based nanocomposites have a lower potential against cathode material, during Lithiation the voltage is ˜0.4 volts. It has a comparable low weight, equivalent to carbon. Silicon is environmentally benign being the second most abundant element in the earth's crust. Silicon has low toxicity and manufacturing is mature based on the learning acquired by the semiconductor industry. This proposed invention will utilize the manufacturing learning gained by this industry to effect a low cost solution.

Silicon anodes, historically have had difficulty maintaining long cycle life. Historically the problem has been capacity fade after cycling. The reversible capacity has been shown to drop by 70%.⁷ The prior silicon anodes underwent a large volume change after Lithiation insertion and extraction. This volume change has been shown to be as much as 420% resulting in material pulverization. The pulverization results in stressed causing the silicon anode to crack and lose of electrical contact and capacity fading. These inherent stresses can cause the SEI, discussed in paragraph [118] to crack and reduce cycle life. These drastic morphology changes results in capacity fading. ⁷ McDowell, M. T., Lee, S. W., Wang, C. Cui, Y. Nano Energy, 1, pages 206-213, 2012

Another important requirement for an anode replacement for LIB is that the Host material, silicon or silicene, is stable in the presence of the electrolyte. When the potential of the lithiated anode is below 1 volt the decomposition of the anode is thermodynamically favorable. Silicon is ˜0.4 volts. A layer forms on the anode material surface known as the solid-electrolyte interface (SEI). This layer is required to be stable and dense and it should be ionically conducting and electrically insulating. The SEI on the anode surface serves as a passivating barrier between the electrolyte and the anode surface. This results in longer cycle life

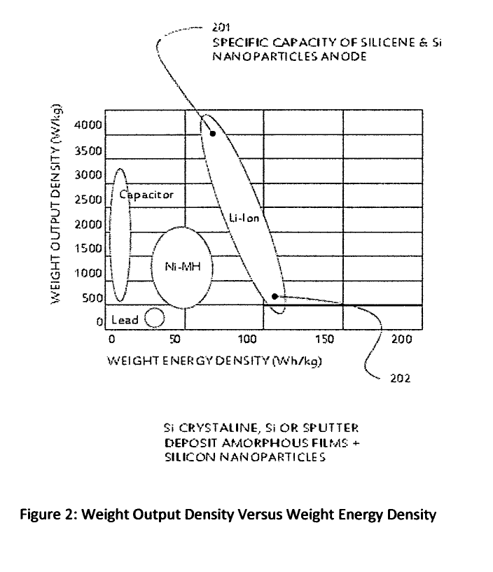

In order to overcome the issues associated with Silicon anodes and to achieve the other requirements for a replacement anode for LIBs, the following invention is described. The proposed invention consists one embodiment silicene sheets of amorphous (702,703), and crystalline (701) silicene layers. See FIG. 3. These are to be deposited by UHV-CVD method. In the second embodiment the silicon nanoporous films, the nanoporous method can deposit amorphous or polysilicon nanoporous films. In the case of polysilicon or crystalline films the use of chemical vapor deposition (CVD) is the method of choice. These films are deposited on the ion collector a thin film of copper. The layer of these films are 3 to 500 angstroms thick. See FIG. 9 [605].

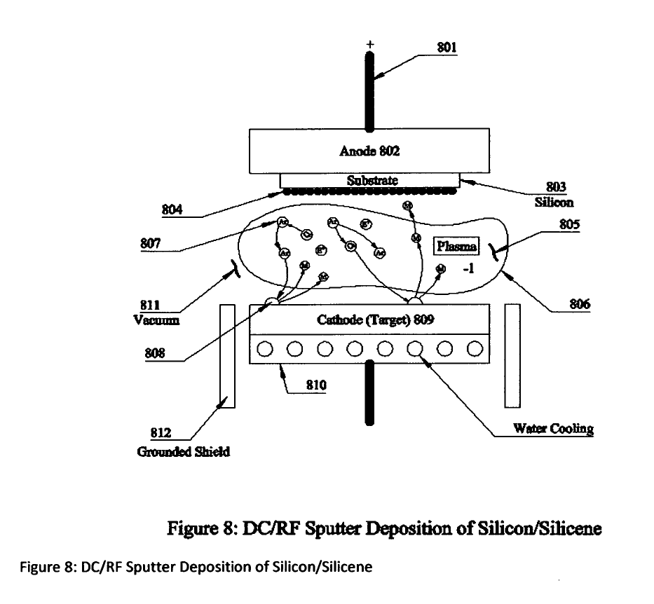

The conditions for the deposition of these nanoporous silicon films is to promote stress by biasing in the case of DC or RF sputter films. In FIG. 8, the conditions for the sputter films are described. On the anode of the DC sputtering systems [801 and 802] a copper ion collector substrate is attached to the anode. A vacuum [811] is created <1×10−7 Torr by evacuation of the chamber. Argon is backfilled into the chamber creating a process pressure of on the order of 1-30 mTorr. The Cathode [810] is grounded and a ground shield surrounds the cathode. The cathode is attached via indium bonding to a silicon target and the bias is negatively charges. The anode is positively charged [801]. The plasma discharge is created by breaking down the argon gas and argon is used to ion bombard the copper substrate [804]. This process removes any oxides or other materials and is carried out at 1-10 mTorr. After bombarding the copper substrate the argon partial pressure is modulated to 1-30 mTorr and the Argon Ions bombard the silicon target causing the silicon material to deposit on the copper ion collector. The amorphous silicon film is deposited on the copper ion collector with a thickness of 3-500 angstroms thick.

The polysilicon and crystalline films use chemical vapor deposition processes to deposit the silicon films. In this case the process will be reduced to practice at a future time when this provisional patent application is converted to a non-provisional patents. In the case of all three silicon films the volume changes induced by Lithiation can be reduced by reducing the size of the particle size of the deposited silicon islands. This can be undertaken by optimizing the processes to deposit the silicon thin films slower, minimizing the amount of argon incorporation in sputtering (FIG. 8) and by optimizing the flow rates and stoichiometric composition in the carrier gases.

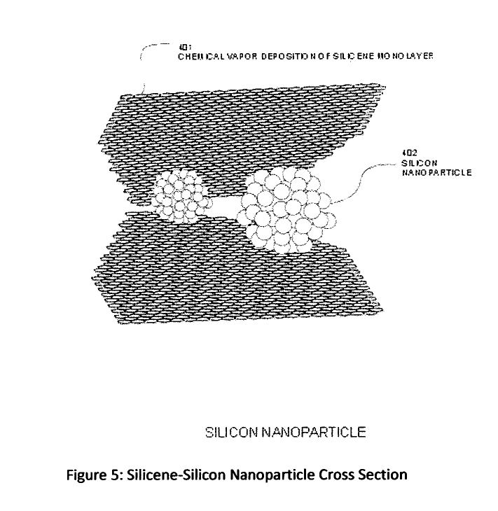

The next steps in this process is to deposit silicon nanoparticles on the silicon thin films. The sizes of the nanoparticles are from 50 to 300 nm. See FIG. 5 [402] This has a direct effect upon the specific capacity of the anode. These will be deposited in either of two ways; in the case of CVD, the gas rations, flow rates and temperature of the substrate modulates the size of the silicon nanoparticles. Before this step a halogen gas such as C12 or F12 will be flowed through the CVD system which will etch the silicon-silicon surface bonds creating bonding sites for the silicon nanoparticles.

In the case of the sputtered amorphous films, the nanoparticles will be sprayed on by dissolving in a casting solvent and prior to this step a argon etch system will be carried out to break the silicon-silicon surface bonds to act as an attachment site for the silicon nanoparticles.

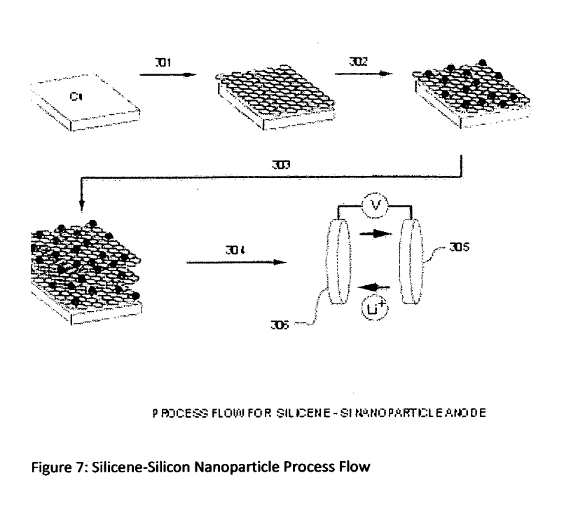

In order to overcome the structural changes discussed previously caused by the Lithiation of the silicon, a three degree nanostructure comprised of either amorphous, polycrystalline or crystalline thin films of reduced domain size covered by silicon nanoparticles covered by silicon this films several times is proposed. See FIG. 5. The first monolayer is deposited on the copper ion collector thin film. (601). The second silicon thin film is deposited, and another layer of silicon nanoparticles are deposited. See FIG. 7. This is repeated several times [302] until a multilayer nanocomposite anode structure is fabricated. [304] The benefits of this method are as follows. This silicon nanostructure has excellent cross plain diffusivity, many in plane silicon vacancies for nanoparticle attachment and much greater tolerance to lithium induced structural deformation.

The nanocomposite has several advantages over other silicon based nanostructures⁸ such as solid Si and Core shell nanowires, silicon nanoparticles nanopowders, hollow Si nanostructures with and without clamping and yolk shells. These include 1.) Structural integrity of the silicon thin films in the lateral and vertical directions to accommodate Lithiation induced structural stresses. 2.) Superior electrical conductivity due to the small silicon domains, and 3.) Optimized ion transport due to the low resistance of the silicon thin film layers. ⁸ Wu, H. and Cui, Y. Nano Today 268, (2012)

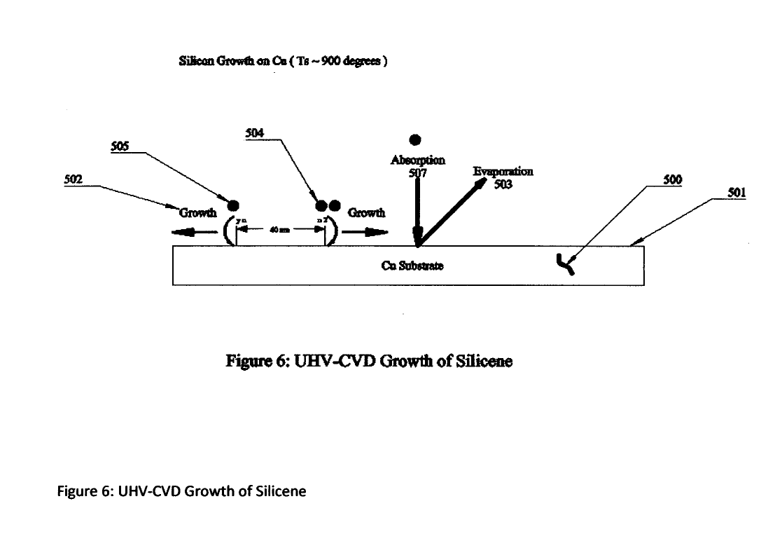

Silicene is deposited in both embodiment, FIGS. 5 and 9 via ultra-high vacuum chemical vapor deposition. See FIG. 6. Starting with the copper substrate, a template layer is grown using epitaxial methods. [301] The films include epitaxial silicon, silver, diborane and Cu2Si. These serve as templates for silicene formation. The silicene is grown by flowing silicon gas over the template layer [305,307] and by heating between 300-500 degrees centigrade, the silicene layers deposit on the surface. [302,304]. Some of the silicene material sublimates off the surface and is re-deposited [309].

In FIG. 9, the nanocomposite cross section is displayed. Voids in the film increases the level of porosity [601,603,604]. The voids provide a location to accommodate the mechanical expansion of the lithiated silicon chemical species. Between the nanoporous films [602] nanoparticles are applied, these are selectively etched resulting in pores that can also accommodate the lithiated silicon chemical species. The nanoparticles also provide mechanical support to alleviate stress associated with mechanical expansion. In addition the voids in the nanoporous films and the nanoparticles provide pathways for the Li to fund bonding with silicon atoms. One variant uses a silicene sheet deposited by UHV-CVD [604] which provides structural integrity in one embodiment. Both nanoparticle processes use rapid thermal anneal to provide surface energy for silicon nanoparticles to bond to defect sites, unattached silicon or carbon bonds. The entire nanostructure is deposited initially on the copper foil used in current SOA LIB fabrication processes. [605] A barrier metal provide better adhesion to the copper layer by depositing a thin layer of Ta, Ti—W or Ti—N.

The foregoing has been a detailed description of illustrative embodiments of the invention. Various modifications and additions can be made without departing from the spirit and scope of this invention. Each of the various embodiments described above may be combined with other described embodiments in order to provide multiple features. Furthermore, while the foregoing describes a number of separate embodiments of the apparatus and method of the present invention, what has been described herein is merely illustrative of the application of the principles of the present invention. For example, the illustrative embodiments can include additional layers to perform further functions or enhance existing, described functions. Likewise, the electrical connectivity of the cell structure with other cells in an array and/or an external conduit is expressly contemplated and highly variable within ordinary skill. More generally, while some ranges of layer thickness and illustrative materials are described herein, these ranges are highly variable. It is expressly contemplated that additional layers, layers having differing thicknesses and/or material choices can be provided to achieve the functional advantages described herein. In addition, directional and locational terms such as “top”, “bottom”, “center”, “front”, “back”, “on”, “under”, “above”, and “below” should be taken as relative conventions only, and not as absolute. Furthermore, it is expressly contemplated that various semiconductor and thin films fabrication techniques can be employed to form the structures described herein. Accordingly, this description is meant to be taken only by way of example, and not to otherwise limit the scope of this invention.

The teachings herein can be embodied in other specific forms without departing from the spirit or essential characteristics thereof. The present embodiments are therefore to be considered in respects as illustrative and not restrictive, the scope of the invention being indicated by the appended claims rather than by the foregoing description, and all changes which come within the meaning and range of the equivalency of the claims are therefore intended to be embraced therein.

What is claimed is:

1. Is a silicon nanostructure based LIB anode consisting of a composite of either amorphous, polysilicon or crystalline silicon films with a total thickness of 3-20 microns. The films are deposited via either RF sputtering, chemical vapor deposition or electrodeposition methods. The films nanoporousity is over a range of 0.1 to 1 gram/cm³. Each silicon nanoporous films is on the order of 1-5 micron thick with the total film thickness of 3-20 microns. Between each layer a non-continuous film of silicon nanoparticles of 50-300 nm in diameter is spread over the surface of the nanoporous silicon thin film. In another embodiment a non-aligned film of carbon nanotubes is spread over the surface of the nanoporous silicon film. Then a non-continuous layer of silicon nanoparticles are applied and annealed by a rapid thermal anneal. The nanoporous silicon film is deposited on a copper film which serves as the anode for a lithium ion battery. The nanostructure accommodates the mechanical expansion of LiSi compounds after intercalation and minimizes particle cracking, Li dendrite formation and exfoliation.

2. The silicon nanostructure wherein claimed in claim one is deposited on a copper foil which serves as the ion collector in lithium ion batteries. This interface between the copper and the silicon has been a problem for reliability. A 1000A±750 angstrom film consisting of Ti—W (90/10%) Ta, or TiN is deposited and serves as a binder for adhesion purposes between the silicon nanoporous film and the copper foil ion collector. This also minimizes copper dissolution and dendrite formation.

3. The nanostructure wherein claimed in claim one can be deposited by RF sputtering. The nanoporousity can be deposited from 0.1 to 1 g/cm³ by increasing the argon partial pressure to 100-200 microns, which incorporates argon gas, and after a thermal anneal leaves voids in the film creating a nanoporous film. In addition the RF energy can be split between the silicon sputtering target and the substrate resulting in increased bias and increased argon gas incorporation within the deposited silicon film.

4. The nanostructure wherein claimed in claim one can be fabricated by electrodeposition and to create nanoporous silicon films. The silicon film is deposited at static voltage of the range 1-5 Volts for a period of time to achieve the silicon film thickness specifications described in claim 1. The deposition electrolyte is 0.3 to 0.6 M SiCl4 and from 0.1 to 0.5 M tetrabutylammonium chloride in CH3CN. Pt foil and wire was used as the reference electrodes. By modulating the static voltage over the range the level of porosity can be changed over the 0.3 to 1.0 g/cm³.

5. The nanostructure wherein claimed in claim one can also be deposited by chemical vapor deposition method at partial pressures of greater than 500 mtorr to 5 atmospheres.

6. The nanostructure wherein claimed in claim one can also be deposited by plasma enhanced chemical vapor deposition method with a RF bias voltage applied to the copper substrate.

7. Silicon nanoparticles can be bonded to the nanoporous silicon surface by using a rapid thermal anneal which causes the nanoparticles to bond to defect sites or open silicon bonds at 200-400 degree centigrade for a total of 1-10 minutes.

8. Silicon nanoparticles can be etched using an anodic process creating voids which can accommodated the mechanical expansion of lithiated silicon and provide mechanical support for the nanocomposite.

9. Silicene is deposited via the ultra-high vacuum chemical vapor deposition (UHV-CVD) method which results in mechanical structure integrity for the silicon nanocomposite structure.

10. Silicene requires a template to grow successfully, this is accomplished by the epitaxial growth of crystalline silicon <100>. Or UHV-CVD Ag<110>, diborane or Cu2Si thin layer to initiate silicene growth.

11. The silicon nanoparticles described in claim 8. can be attached to the silicene sheets surfaces by chemical functionalization etching or rapid thermal annealing, increasing the mechanical integrity of the nanocomposite anode structure.

12. The silicene nanocomposite consists of silicene sheets with in plane silicon vacancies. Electrochemically active nanoparticles, from 50-300 nm in diameters are sandwiched between the silicene sheets.

13. Silicene requires a template to grow successfully, this is accomplished by the epitaxial growth of crystalline silicon <100>. or UHV-CVD Ag<110>, diborane or Cu2Si thin layers to initiate silicene growth, which are grown on the copper foil used as the ion collector in lithium ion battery anodes.

14. Silicene is deposited via the ultra-high vacuum chemical vapor deposition (UHV-CVD) method which results in mechanical structure integrity for the silicon nanocomposite structure. This method is undertaken at 1×10-7 Torr base pressure, process pressure is 1×10-5 Torr process pressure in argon and followed by an anneal at 400 degrees centigrade.

15. Silicon nanoparticles can be bonded to the silicene surface by using a rapid thermal anneal which causes the nanoparticles to bond to defect sites or open silicon bonds at 200-400 degree centigrade for a total of 1-10 minutes.

16. The silicene sheets are aligned to each other after the initial sheet is deposited the underlying sheet serves as a template for additional silicene sheets.

17. Silicon nanoparticles can be etched using an anodic process creating voids which can accommodated the mechanical expansion of lithiated silicon and provide mechanical support for the nanocomposite.

18. Silicon vacancies are created with either wet etch or dry etch methods, possibly followed by sonication in the wet etch method.
